(19) United States
(12) Patent Application Publication
(10) Pub. No.: US 2026/0130125 A1
(43) Pub. Date: May 7, 2026

(54) RESONANT CIRCUIT DEVICE COMPRISING QUBIT AND METHOD FOR MANUFACTURING THE SAME

(71) Applicant: POSTECH RESEARCH AND BUSINESS DEVELOPMENT FOUNDATION, Pohang-si (KR)

(72) Inventors: Jae Yoon SHIM, Pohang-si (KR); Seung Young SEO, Pohang-si (KR)

(73) Assignee: POSTECH RESEARCH AND BUSINESS DEVELOPMENT FOUNDATION, Pohang-si (KR)

(21) Appl. No.: 19/372,907

(22) Filed: Oct. 29, 2025

(30) Foreign Application Priority Data
Nov. 6, 2024 (KR) 10-2024-0155976

(51) Int. Cl. H10N 60/12; G06N 10/40; H01P 3/08; H01P 7/08; H01P 11/00; H10N 60/01

(52) U.S. Cl. CPC H10N 60/12; G06N 10/40; H01P 3/08; H01P 7/08; H01P 11/008; H10N 60/0912

(57) ABSTRACT

A resonant circuit device is provided. A resonant circuit device comprising a qubit, comprising: a first qubit; a first lower electrode disposed spaced apart from the first qubit in a first direction; an insulating layer disposed on the first qubit and the first lower electrode; a first upper electrode disposed on the insulating layer; a first through via connecting the first qubit and the first upper electrode and disposed through the insulating layer; and a second through via connecting the first upper electrode and the first lower electrode and disposed through the insulating layer.

### CROSS-REFERENCE TO RELATED APPLICATION

This application claims priority under 35 U.S. C § 119 to Korean Patent Application No. 10-2024-0155976 filed on Nov. 6, 2024, in the Korean Intellectual Property Office, the entire contents of which are hereby incorporated by reference.

### TECHNICAL FIELD

The disclosure relates to a resonant circuit device comprising a qubit and a method for manufacturing the same.

### BACKGROUND

The content set forth in this section merely provides background information on the present embodiments and does not constitute prior art.

A resonant circuit comprising a qubit has comprised a structure in which the qubit and the resonator are disposed on a two-dimensional plane. In addition, the layer containing the qubit and the resonator and another layer could be connected via a through via (e.g., through-silicon via (TSV)).

Furthermore, this has resulted in a problem that it is difficult to reduce the area occupied by the resonator itself, and the through vias have been treated as a secondary component that only serves for connection.

Therefore, there has been a need for a structure that can reduce the area occupied by the resonator itself.

### SUMMARY

It is an object of the present disclosure to provide a resonant circuit device comprising a qubit that can reduce the area occupied by a resonator, and a method for manufacturing the same.

In addition, it is an object of the present disclosure to provide a resonant circuit device comprising a qubit that can determine the resonant frequency of a resonator by using through vias, and a method for manufacturing the same.

The objects of the present disclosure are not limited to the objects mentioned above, and other objects and advantages of the present disclosure that have not been mentioned can be understood by the following description and will be more clearly understood by the embodiments of the present disclosure. Further, it will be readily appreciated that the objects and advantages of the present disclosure can be realized by the means set forth in the claims and combinations thereof.

According to some aspects of the disclosure, a resonant circuit device comprising a qubit, comprising: a first qubit; a first lower electrode disposed spaced apart from the first qubit in a first direction; an insulating layer disposed on the first qubit and the first lower electrode; a first upper electrode disposed on the insulating layer; a first through via connecting the first qubit and the first upper electrode and disposed through the insulating layer; and a second through via connecting the first upper electrode and the first lower electrode and disposed through the insulating layer.

According to some aspects, a plurality of upper electrodes disposed on the insulating layer and spaced apart from each other; a plurality of lower electrodes disposed under the insulating layer and spaced apart from each other; and a plurality of through vias connecting each of the plurality of upper electrodes and each of the plurality of lower electrodes and passing through the insulating layer, wherein the plurality of upper electrodes comprises the first upper electrode, the plurality of lower electrodes comprises the first lower electrode, the plurality of through vias comprises the second through via, and the plurality of through vias is spaced apart from the first through via, and wherein a resonant frequency of the resonant circuit device is determined based on a combined number of the first through via and the plurality of through vias.

According to some aspects, wherein the first through via and the second through via extend along a second direction intersecting the first direction.

According to some aspects, wherein a lower part of the first through via is in direct contact with the first qubit, an upper part of the first through via is in direct contact with a first portion of the first upper electrode, an upper part of the second through via is in direct contact with a second portion of the first upper electrode, and a lower part of the second through via is in direct contact with a first portion of the first lower electrode.

According to some aspects, a second qubit disposed spaced apart from the first qubit; a second upper electrode spaced apart from the first upper electrode and disposed on the insulating layer; a second lower electrode spaced apart from the first lower electrode and disposed under the insulating layer; and a third through via connecting the second upper electrode and the second qubit and disposed through the insulating layer, wherein the first lower electrode and the second lower electrode are disposed between the first qubit and the second qubit.

According to some aspects, a plurality of upper electrodes disposed on the insulating layer and spaced apart from each other; a plurality of lower electrodes disposed under the insulating layer and spaced apart from each other; and a plurality of through vias connecting each of the plurality of upper electrodes and each of the plurality of lower electrodes and passing through the insulating layer, wherein the plurality of upper electrodes comprises the first upper electrode and the second upper electrode, the plurality of lower electrodes comprises the first lower electrode and the second lower electrode, the plurality of through vias comprises the second through via, and the plurality of through vias is spaced apart from each of the first through via and the third through via.

According to some aspects, wherein each of the plurality of upper electrodes is disposed spaced apart from each other along the first direction, and each of the plurality of through vias is disposed spaced apart from each other along the first direction.

According to some aspects, wherein each of the plurality of upper electrodes comprises:

a first upper electrode group extending in the first direction; and a second upper electrode group extending along a third direction intersecting the first direction, wherein the plurality of through vias further comprises a fourth through via spaced apart from the second through via in the third direction.

According to some aspects, a transmission line spaced apart from the first upper electrode and disposed on the insulating layer; a second upper electrode spaced apart from the first upper electrode and disposed on the insulating layer; a second lower electrode spaced apart from the first lower electrode and disposed under the insulating layer; and a third through via connecting the second upper electrode and the second lower electrode and disposed through the insulating layer, wherein the second upper electrode is disposed between the first upper electrode and the transmission line, and the second upper electrode and the transmission line are connected to each other.

According to some aspects, a plurality of upper electrodes disposed on the insulating layer and spaced apart from each other; a plurality of lower electrodes disposed under the insulating layer and spaced apart from each other; and a plurality of through vias connecting each of the plurality of upper electrodes and each of the plurality of lower electrodes and passing through the insulating layer, wherein the plurality of upper electrodes comprises the first upper electrode and the second upper electrode, the plurality of lower electrodes comprises the first lower electrode and the second lower electrode, the plurality of through vias comprises the second through via, and the plurality of through vias is spaced apart from each of the first through via and the third through via.

According to some aspects, wherein the first upper electrode and the first through via include the same material, and the first lower electrode includes a material different from that included in each of the first upper electrode and the first through via.

According to some aspects, wherein each of the plurality of upper electrodes comprises:

a first upper electrode group extending in the first direction; and a second upper electrode group extending along a third direction intersecting the first direction, wherein the plurality of through vias further comprises a fourth through via spaced apart from the second through via in the third direction.

According to some aspects of the disclosure, a resonant circuit device comprising a qubit, comprising: a first layer comprising a first qubit and a plurality of lower electrodes disposed spaced apart from the first qubit in a first direction; an insulating layer on the first layer; and a second layer disposed on the insulating layer and comprising a plurality of upper electrodes, wherein the insulating layer comprises: a plurality of through vias connecting each of the plurality of lower electrodes and each of the plurality of upper electrodes and passing through the insulating layer; and a first through via connecting a first portion of a first upper electrode of the plurality of upper electrodes and the first qubit and passing through the insulating layer, and wherein a resonant frequency is determined based on a combined number of the plurality of through vias and the first through via.

According to some aspects, wherein a lower part of the first through via is in direct contact with the first qubit, an upper part of the first through via is in direct contact with a first portion of the first upper electrode, the plurality of through vias comprises a second through via, and the plurality of lower electrodes comprises a first lower electrode, an upper part of the second through via is in direct contact with a second portion of the first upper electrode, and a lower part of the second through via is in direct contact with a first portion of the first lower electrode.

According to some aspects, a second qubit spaced apart from the first qubit and disposed in the first layer, wherein the plurality of upper electrodes comprises a second upper electrode spaced apart from the first upper electrode, the plurality of lower electrodes comprises a first lower electrode disposed between the first qubit and the second qubit, and the plurality of through vias comprises a second through via connecting a second portion of the first upper electrode and a first portion of the first lower electrode and passing through the insulating layer.

According to some aspects, wherein each of the plurality of upper electrodes is disposed spaced apart from each other along the first direction, and each of the plurality of through vias is disposed spaced apart from each other along the first direction.

According to some aspects, wherein each of the plurality of upper electrodes comprises:

a first upper electrode group extending in the first direction; and a second upper electrode group extending along a third direction intersecting the first direction, wherein the plurality of through vias further comprises a fourth through via spaced apart from the second through via in the third direction.

According to some aspects, a transmission line spaced apart from the first upper electrode and disposed on the insulating layer, wherein the plurality of upper electrodes comprises a second upper electrode spaced apart from the first upper electrode, the plurality of lower electrodes comprises a first lower electrode and a second lower electrode disposed between the first qubit and the transmission line and spaced apart from each other, the plurality of through vias comprises a second through via connecting the second upper electrode and the second lower electrode and disposed through the insulating layer, the second upper electrode is disposed between the first upper electrode and the transmission line, and the second upper electrode and the transmission line are connected to each other.

According to some aspects, wherein each of the plurality of upper electrodes is disposed spaced apart from each other along the first direction, and each of the plurality of through vias is disposed spaced apart from each other along the first direction.

According to some aspects of the disclosure, a method of manufacturing a resonant circuit device comprising a qubit, comprising: forming a first layer comprising a first qubit and a plurality of lower electrodes disposed spaced apart from the first qubit; forming an insulating layer on the first layer; forming a patterned first mask layer on the insulating layer; forming a plurality of through via holes, which passes through the insulating layer, exposes part of the first qubit, and exposes part of each of the plurality of lower electrodes, based on the patterned first mask layer; forming a plurality of through vias by filling the plurality of through via holes with a through via material; forming a through via material layer by covering an upper surface of the insulating layer and the plurality of through vias with the through via material; forming a patterned second mask layer on the through via material layer; and forming a plurality of upper electrodes, which exposes part of the upper surface of the insulating layer and is connected to each of the plurality of through vias, based on the patterned second mask layer.

The resonant circuit device comprising a qubit and the method for manufacturing the same of the present disclosure can reduce the area occupied by the resonator by constructing the resonator using through vias.

Furthermore, the resonant circuit device comprising a qubit and the method for manufacturing the same of the present disclosure can determine the resonant frequency of the resonator by using through vias.

In addition to the foregoing description, specific effects of the present disclosure will be stated together while describing specific details for implementing the present disclosure below.

### BRIEF DESCRIPTION OF THE DRAWINGS

FIG. 1 is a plan view of a resonant circuit device comprising a qubit according to some embodiments of the present disclosure.

FIG. 2 is a cross-sectional view taken along the line X-X′ in FIG. 1.

FIG. 3 is an enlarged view of region A in FIG. 2.

FIG. 4 is an enlarged view of region B in FIG. 2.

FIG. 5 is a plan view of a resonant circuit device comprising a qubit according to some embodiments of the present disclosure.

FIG. 6 is a cross-sectional view taken along the line Y-Y′ in FIG. 5.

FIG. 7 is a plan view of a resonant circuit device comprising a qubit according to some embodiments of the present disclosure.

FIG. 8 is a cross-sectional view taken along the line M-M′ in FIG. 7.

FIG. 9 is a plan view of a resonant circuit device comprising a qubit according to some embodiments of the present disclosure.

FIG. 10 is a cross-sectional view taken along the line N-N′ in FIG. 9.

FIG. 11 is a flowchart for describing a method of manufacturing a resonant circuit device comprising a qubit according to some embodiments of the present disclosure.

FIG. 12 is part of a cross-sectional view for describing step S100 of FIG. 11.

FIG. 13 is part of a cross-sectional view for describing steps S200 and S300 of FIG. 11.

FIG. 14 is part of a cross-sectional view for describing step S400 of FIG. 11.

FIG. 15 is part of a cross-sectional view for describing steps S500 and S600 of FIG. 11.

FIG. 16 is part of a cross-sectional view for describing step S700 of FIG. 11.

FIG. 17 is part of a cross-sectional view for describing step S800 of FIG. 11.

### DETAILED DESCRIPTION

The terms or words used in the disclosure and the claims should not be construed as limited to their ordinary or lexical meanings. They should be construed as the meaning and concept in line with the technical idea of the disclosure based on the principle that the inventor can define the concept of terms or words in order to describe his/her own inventive concept in the best possible way. Further, since the embodiment described herein and the configurations illustrated in the drawings are merely one embodiment in which the disclosure is realized and do not represent all the technical ideas of the disclosure, it should be understood that there may be various equivalents, variations, and applicable examples that can replace them at the time of filing this application.

Although terms such as first, second, A, B, etc. used in the description and the claims may be used to describe various components, the components should not be limited by these terms. These terms are only used to differentiate one component from another. For example, a first component may be referred to as a second component, and similarly, a second component may be referred to as a first component, without departing from the scope of the disclosure. The term ‘and/or’ includes a combination of a plurality of related listed items or any item of the plurality of related listed items.

The terms used in the description and the claims are merely used to describe particular embodiments and are not intended to limit the disclosure. Singular forms are intended to include plural forms unless the context clearly indicates otherwise. In the application, terms such as “comprise,” “comprise,” “have,” etc. should be understood as not precluding the possibility of existence or addition of features, numbers, steps, operations, components, parts, or combinations thereof described herein.

Unless otherwise defined, the phrases “A, B, or C,” “at least one of A, B, or C,” or “at least one of A, B, and C” may refer to only A, only B, only C, both A and B, both A and C, both B and C, all of A, B, and C, or any combination thereof.

Unless being defined otherwise, all terms used herein, including technical or scientific terms, have the same meaning as commonly understood by those skilled in the art to which the disclosure pertains.

Terms such as those defined in commonly used dictionaries should be construed as having a meaning consistent with the meaning in the context of the relevant art, and are not to be construed in an ideal or excessively formal sense unless explicitly defined in the application. In addition, each configuration, procedure, process, method, or the like included in each embodiment of the disclosure may be shared to the extent that they are not technically contradictory to each other.

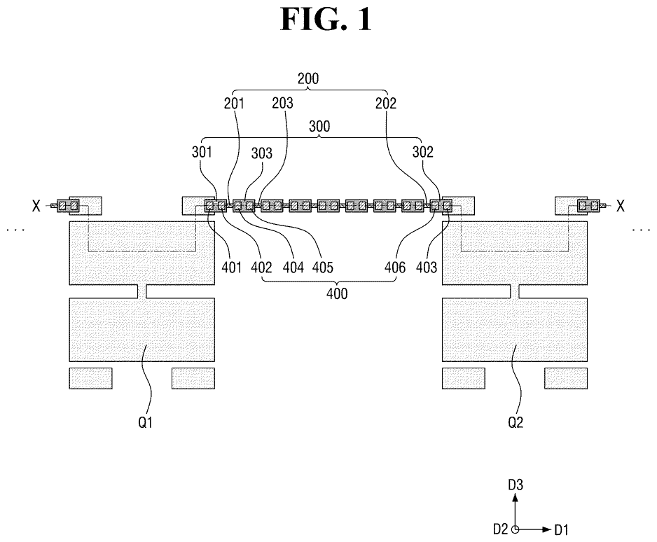

Hereinafter, a resonant circuit device comprising a qubit according to some embodiments of the present disclosure will be described with reference to FIGS. 1 to 4.

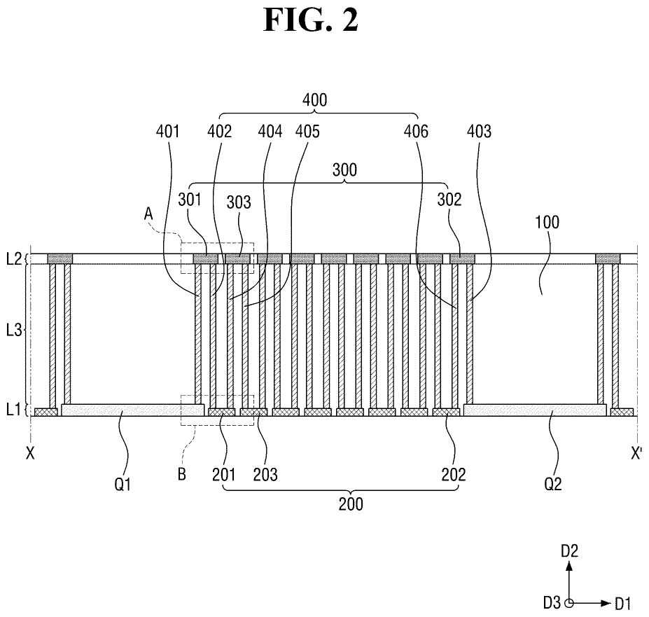

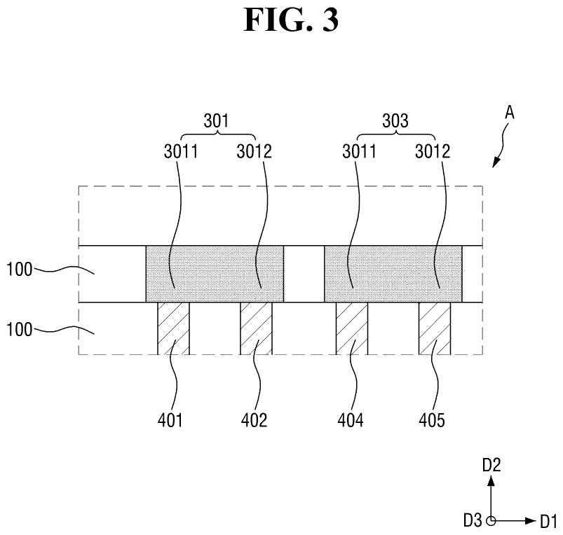

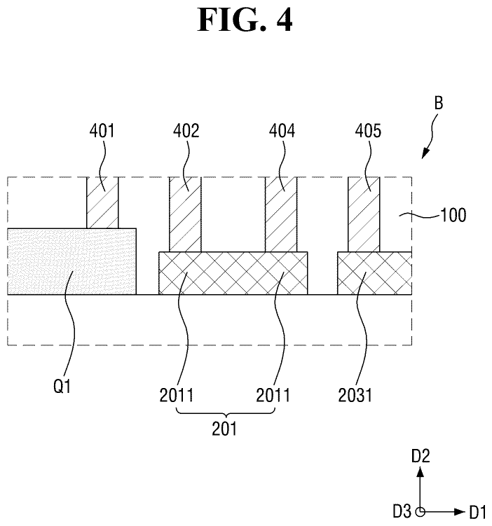

FIG. 1 is a plan view of a resonant circuit device comprising a qubit according to some embodiments of the present disclosure. FIG. 2 is a cross-sectional view taken along the line X-X′ in FIG. 1. FIG. 3 is an enlarged view of region A in FIG. 2. FIG. 4 is an enlarged view of region B in FIG. 2.

The illustration of an insulating layer L3 and an insulating material 100 is omitted in FIG. 1 for clarity.

Referring to FIGS. 1, 2, 3, and 4, the resonant circuit device comprising a qubit may comprise a first qubit Q1, a plurality of lower electrodes 200, the insulating layer L3, a plurality of upper electrodes 300, and a plurality of through vias 400. The resonator of the resonant circuit device may comprise a first through via 401, the plurality of through vias 400, a third through via 403, the plurality of upper electrodes 300, and the plurality of lower electrodes 200.

In some embodiments, the first qubit Q1 may be connected to a second qubit Q2 via the plurality of lower electrodes 200, the plurality of upper electrodes 300, and the plurality of through vias 400.

The second qubit Q2 may be disposed spaced apart from the first qubit Q1 in a first direction D1. The plurality of lower electrodes 200 may be disposed between the first qubit Q1 and the second qubit Q2.

The first qubit Q1 and the second qubit Q2 may contain any one of Al, Nb, NbN, NbTiN, tantalum, and tantalum nitride.

The first qubit Q1, the plurality of lower electrodes 200, and the second qubit Q2 may be disposed in a first layer L1.

The plurality of lower electrodes 200 may be disposed spaced apart from the first qubit Q1 in the first direction D1. Each lower electrode comprised in the plurality of lower electrodes 200 may be disposed spaced apart from each other.

In some embodiments, each of the lower electrodes comprised in the plurality of lower electrodes 200 may extend along the first direction D1. Each of the lower electrodes comprised in the plurality of lower electrodes 200 may be arranged in a line between the first qubit Q1 and the second qubit Q2 while being spaced apart from each other.

The plurality of lower electrodes 200 may comprise a first lower electrode 201, a second lower electrode 202, and a third lower electrode 203. The first lower electrode 201, the second lower electrode 202, and the third lower electrode 203 may be spaced apart from each other. Each of the first lower electrode 201, the second lower electrode 202, and the third lower electrode 203 may be disposed along the first direction D1. Each of the first lower electrode 201, the second lower electrode 202, and the third lower electrode 203 may be disposed spaced apart from the first qubit Q1 in the first direction D1. The first lower electrode 201, the second lower electrode 202, and the third lower electrode 203 may be disposed between the first qubit Q1 and the second qubit Q2.

The first layer L1 may comprise part of the insulating material 100. The insulating material 100 may be disposed between the first qubit Q1 and the first lower electrode 201, between each of the plurality of lower electrodes 200, and between the second lower electrode 202 and the second qubit Q2.

The insulating layer L3 may be disposed on the first layer L1. The insulating layer L3 may be disposed on the first qubit Q1, the second qubit Q2, and the plurality of lower electrodes 200. The plurality of lower electrodes 200 may be disposed under the insulating layer L3. For example, each of the first lower electrode 201, the second lower electrode 202, and the third lower electrode 203 may be disposed under the insulating layer L3.

The insulating layer L3 may comprise another part of the insulating material 100.

The insulating layer L3 may comprise the plurality of through vias 400, the first through via 401, and the third through via 03, which are disposed through the insulating layer L3.

The plurality of through vias 400 may comprise a second through via 402, a fourth through via 404, a fifth through via 405, and a sixth through via 406.

The plurality of through vias 400 may be disposed spaced apart from the first through via 401 and the third through via 403, respectively. Each of the through vias comprised in the plurality of through vias 400 may be disposed spaced apart from each other. The plurality of through vias 400 may be disposed between the first through via 401 and the third through via 403.

Each of the first through via 401, the third through via 403, and the plurality of through vias 400 may pass through the insulating layer L3 so as to connect the second layer L2 and the first layer L1. Each of the first through via 401, the third through via 403, and the plurality of through vias 400 may extend within the insulating layer L3 along a second direction D2. The second direction D2 may be a direction intersecting the first direction D1. The second direction D2 may be, for example, a direction from the first layer L1 toward the second layer L2.

In some embodiments, each of the plurality of through vias 400 may be disposed to correspond to the disposition of each of the plurality of lower electrodes 200. Each of the plurality of through vias 400 may be arranged in a line between the first qubit Q1 and the second qubit Q2 while being spaced apart from each other. Each of the plurality of through vias 400 may be disposed along the first direction D1.

The insulating material 100 may be disposed between each of the first through via 401, the third through via 403, and the plurality of through vias 400. The insulating material 100 may be disposed on the first qubit Q1 and the second qubit Q2.

The second layer L2 may be disposed on the insulating layer L3. The second layer L2 may be disposed on the first through via 401, the third through via 403, and the plurality of through vias 400.

The second layer L2 may comprise the other part of the insulating material 100.

The second layer L2 may comprise the plurality of upper electrodes 300 disposed on the insulating layer L3. Each upper electrode comprised in the plurality of upper electrodes 300 may be disposed spaced apart from each other.

In some embodiments, each of the upper electrodes comprised in the plurality of upper electrodes 300 may extend along the first direction D1. Each of the upper electrodes comprised in the plurality of upper electrodes 300 may be arranged in a line between the first qubit Q1 and the second qubit Q2 while being spaced apart from each other.

The plurality of upper electrodes 300 may comprise a first upper electrode 301, a second upper electrode 302, and a third upper electrode 303. The first upper electrode 301, the second upper electrode 302, and the third upper electrode 303 may be spaced apart from each other. Each of the first upper electrode 301, the second upper electrode 302, and the third upper electrode 303 may be disposed along the first direction D1.

The first through via 401, the third through via 403, and the plurality of through vias 400 may connect the first layer L1 and the second layer L2. The plurality of through vias 400 may connect each of the plurality of upper electrodes 300 and each of the plurality of lower electrodes 200.

The first through via 401 may connect the first qubit Q1 and the first upper electrode 301. The first through via 401 may extend from a first portion 3011 of the first upper electrode 301 and may be connected to the first qubit Q1 through the insulating layer L3. The upper part of the first through via 401 may be in direct contact with the first portion 3011 of the first upper electrode 301, and the lower part of the first through via 401 may be in direct contact with the first qubit Q1.

Each of the plurality of through vias 400 may be in direct contact with each of the plurality of upper electrodes 300 and also with each of the plurality of lower electrodes 200.

The second through via 402 comprised in the plurality of through vias 400 may connect the first upper electrode 301 and the first lower electrode 201. The second through via 402 may extend from a second portion 3012 of the first upper electrode 301 and may be connected to a first portion 2011 of the first lower electrode 201 through the insulating layer L3. The upper part of the second through via 402 may be in direct contact with the second portion 3012 of the first upper electrode 301, and the lower part of the second through via 402 may be in direct contact with the first portion 2011 of the first lower electrode 201.

The first upper electrode 301 may be connected to the first qubit Q1 by the first through via 401 and may be connected to the first lower electrode 201 by the second through via 402.

The third through via 403 may connect the second qubit Q2 and the second upper electrode 302. The third through via 403 may extend from a portion of the second upper electrode 302 and may be connected to the second qubit Q2 through the insulating layer L3. The upper part of the third through via 403 may be in direct contact with a portion of the second upper electrode 302, and the lower part of the third through via 403 may be in direct contact with the second qubit Q2.

The fourth through via 404 comprised in the plurality of through vias 400 may connect the third upper electrode 303 and the first lower electrode 201. The fourth through via 404 may extend from a first portion 3031 of the third upper electrode 303 and may be connected to a second portion 2012 of the first lower electrode 201 through the insulating layer L3. The upper part of the fourth through via 404 may be in direct contact with the first portion 3031 of the third upper electrode 303, and the lower part of the fourth through via 404 may be in direct contact with the second portion 2012 of the first lower electrode 201.

The fifth through via 405 comprised in the plurality of through vias 400 may connect the third upper electrode 303 and the third lower electrode 203. The fifth through via 405 may extend from a second portion 3032 of the third upper electrode 303 and may be connected to a first portion 2031 of the third lower electrode 203 through the insulating layer L3. The upper part of the fifth through via 405 may be in direct contact with the second portion 3032 of the third upper electrode 303, and the lower part of the fifth through via 405 may be in direct contact with the first portion 2031 of the third lower electrode 203.

The third upper electrode 303 may be connected to the first lower electrode 201 by the fourth through via 404 and may be connected to the third lower electrode 203 by the fourth through via 404.

The first through via 401, the third through via 403, and the plurality of through vias 400 may contain a material that can be deposited by an atomic layer deposition (ALD) method. The first through via 401, the third through via 403, and the plurality of through vias 400 may contain any one of niobium, niobium nitride, and titanium nitride.

The first through via 401, the third through via 403, the plurality of through vias 400, and the plurality of upper electrodes 300 may contain the same material.

Based on the combined number of the first through via 401, the third through via 403, and the plurality of through vias 400, the resonant frequency of the resonant circuit device may be determined. The resonant frequency of the resonant circuit device may be determined by the length of the first through via 401, the length of the third through via 403, the length of each of the plurality of upper electrodes 300, the length of each of the plurality of through vias 400, and the length of each of the plurality of lower electrodes 200. Therefore, an increase in the combined number of the first through via 401, the third through via 403, and the plurality of through vias 400 may result in a higher resonant frequency, and a decrease in the combined number of the first through via 401, the third through via 403, and the plurality of through vias 400 may result in a lower resonant frequency. Further, by adjusting the length of at least one of each of the plurality of upper electrodes 300 and each of the plurality of lower electrodes 200, the resonant frequency can be precisely adjusted. An increase in the length of at least one of each of the plurality of upper electrodes 300 and each of the plurality of lower electrodes 200 may result in a higher resonant frequency, and a decrease in the length of at least one of each of the plurality of upper electrodes 300 and each of the plurality of lower electrodes 200 may also result in a lower resonant frequency.

The resonant circuit device according to an embodiment of the present disclosure may comprise the first through via 401, the third through via 403, and the plurality of through vias 400 in a degree sufficient to adjust the resonant frequency, and the resonant frequency can be determined based on the combined number of the first through via 401, the third through via 403, and the plurality of through vias 400. The first through via 401, the third through via 403, and the plurality of through vias 400 of the resonant circuit device according to an embodiment of the present disclosure do not simply connect the first layer L1 and the second layer L2, but can also cause an increase or decrease in the resonant frequency.

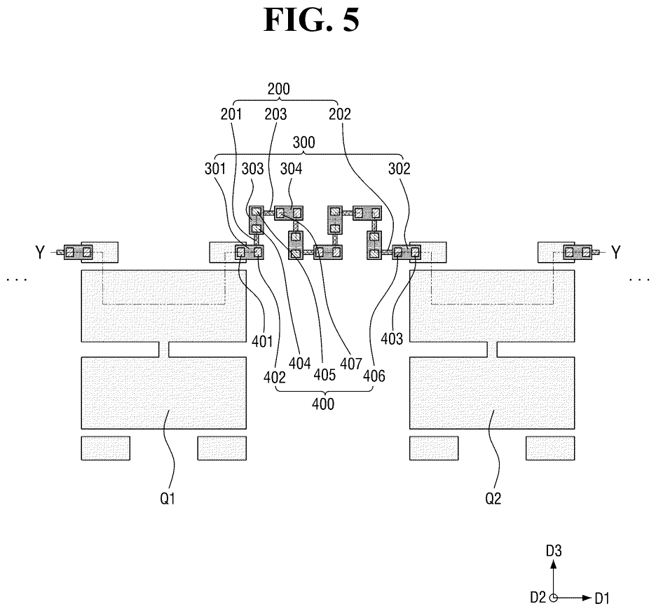

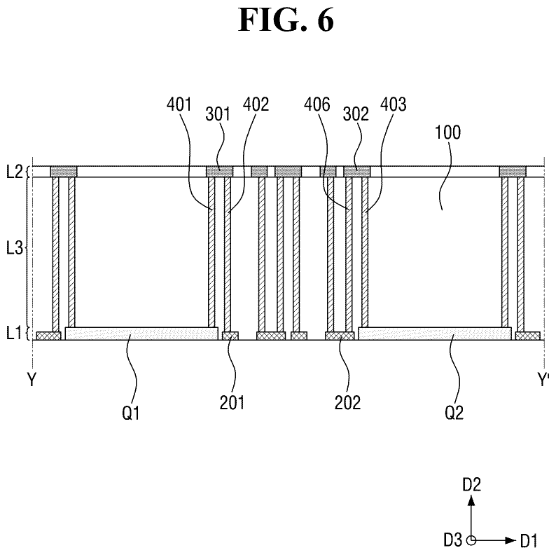

In the following, a resonant circuit device comprising a qubit according to some embodiments of the present disclosure will be described with reference to FIGS. 5 and 6. For clarity of description, any part that overlaps with what has already been described will be either simplified or omitted.

FIG. 5 is a plan view of a resonant circuit device comprising a qubit according to some embodiments of the present disclosure. FIG. 6 is a cross-sectional view taken along the line Y-Y′ in FIG. 5.

The illustration of an insulating layer L3 and an insulating material 100 is omitted in FIG. 5 for clarity.

Referring to FIGS. 5 and 6, a plurality of upper electrodes 300 of the resonant circuit device comprising a qubit according to some embodiments of the present disclosure may not be arranged in a line between a first qubit Q1 and a second qubit Q2. The plurality of upper electrodes 300 may comprise a first upper electrode group and a second upper electrode group.

The first upper electrode group may be part of the plurality of upper electrodes 300 extending in a first direction D1. The first upper electrode group may comprise, for example, a first upper electrode 301 and a second upper electrode 302.

The second upper electrode group may be another part of the plurality of upper electrodes 300 extending in a third direction D3. The second upper electrode group may comprise, for example, a third upper electrode 303. The third direction D3 may be a direction intersecting the first direction D1 and the second direction D2.

Each of the plurality of upper electrodes 300 may be disposed to be spaced apart from each other in the first direction D1 and may also be disposed to be spaced apart from each other in the third direction D3.

For example, the first upper electrode 301 may be connected to a first lower electrode 201 by a second through via 402. The first lower electrode 201 may be connected to the third upper electrode 303 by a fourth through via 404. The first upper electrode 301 and the third upper electrode 303 may be spaced apart from each other along the third direction D3. The first upper electrode 301 may extend in the first direction D1, and the third upper electrode 303 may extend in the third direction D3.

For example, the third upper electrode 303 may be connected to a third lower electrode 203 by a fifth through via 405. The third lower electrode 203 may be connected to the third upper electrode 303 by a seventh through via 407. The third upper electrode 303 and a fourth upper electrode 304 may be spaced apart from each other along a direction intersecting the third direction D3. The third upper electrode 303 may extend in the third direction D3, and the fourth upper electrode 304 may extend in the first direction D1.

The plurality of through vias 400 may be disposed according to the disposition of the plurality of upper electrodes 300. For example, the second through via 402 and the fourth through via 404 connected to the first lower electrode 201 may be disposed such that as the first upper electrode 301 and the third upper electrode 303 are disposed to be spaced apart along the third direction D3, the second through via 402 and the fourth through via 404 are also spaced apart along the third direction D3. For example, the fourth through via 404 and the fifth through via 405 connected to the third upper electrode 303 may be disposed such that as the third upper electrode 303 extends in the third direction D3, the fourth through via 404 and the fifth through via 405 are also spaced apart along the third direction D3.

The plurality of lower electrodes 200 may be disposed according to the disposition of the plurality of upper electrodes 300. For example, the first lower electrode 201 connected to the first upper electrode 301 and to the third upper electrode 303 may extend along the third direction D3 as the first upper electrode 301 and the third upper electrode 303 are disposed to be spaced apart along the third direction D3.

The plurality of upper electrodes 300, the plurality of through vias 400, and the plurality of lower electrodes 200 are shown as being disposed in a certain shape between the first qubit Q1 and the second qubit Q2 in FIG. 5, but are not limited thereto. As long as the first qubit Q1, the plurality of upper electrodes 300, the plurality of through vias 400, the plurality of lower electrodes 200, and the second qubit Q2 can be connected between the first qubit Q1 and the second qubit Q2, they can be disposed in other shapes as a matter of course.

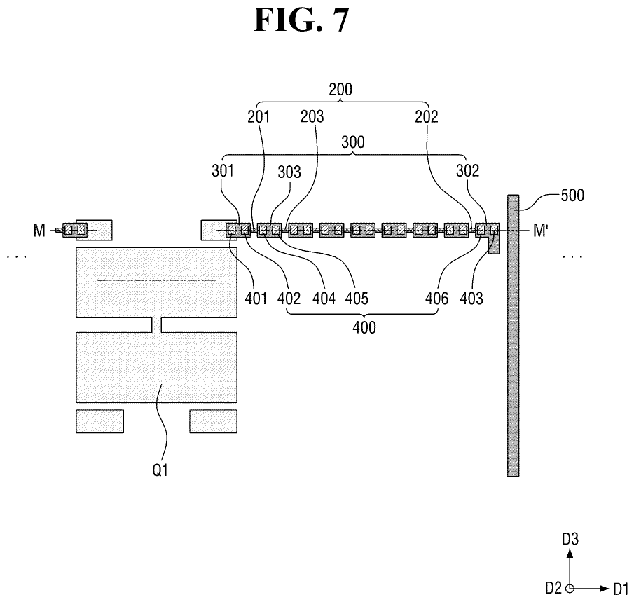

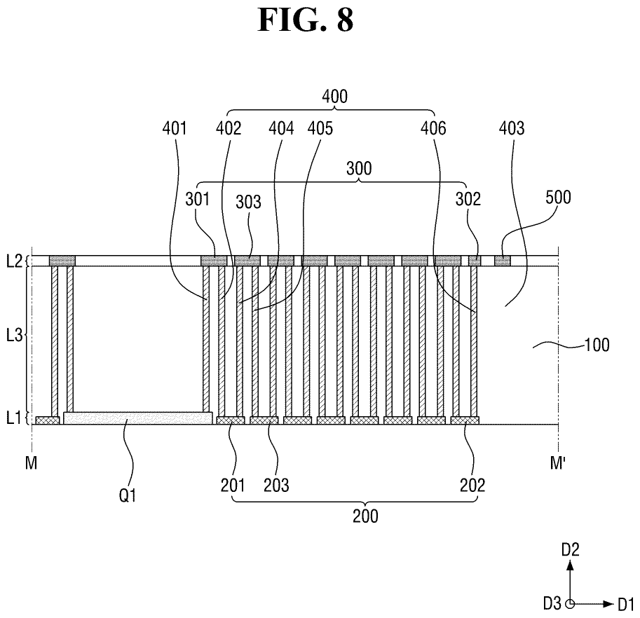

In the following, a resonant circuit device comprising a qubit according to some embodiments of the present disclosure will be described with reference to FIGS. 7 and 8. For clarity of description, any part that overlaps with what has already been described will be either simplified or omitted.

FIG. 7 is a plan view of a resonant circuit device comprising a qubit according to some embodiments of the present disclosure. FIG. 8 is a cross-sectional view taken along the line M-M′ in FIG. 7.

The illustration of an insulating layer L3 and an insulating material 100 is omitted in FIG. 7 for clarity.

Referring to FIGS. 7 and 8, the resonant circuit device comprising a qubit according to some embodiments of the present disclosure may comprise a transmission line 500. The transmission line 500 may be connected to a first qubit Q1 via a resonator. The resonator may comprise a first through via 401, a third through via 403, a plurality of through vias 400, a plurality of upper electrodes 300, and a plurality of lower electrodes 200.

The transmission line 500 may be spaced apart from the plurality of upper electrodes 300 and may be disposed on the insulating layer L3.

A second upper electrode 302 may be disposed between a first upper electrode 301 and the transmission line 500. The second upper electrode 302 may be electrically connected to the transmission line 500. The second upper electrode 302 may be connected to the transmission line 500 via, for example, a capacitor.

Between the first qubit Q1 and the transmission line 500, the plurality of upper electrodes 300, the plurality of through vias 400, and the plurality of lower electrodes 200 may be arranged in a line. For example, each of the plurality of upper electrodes 300 may be disposed spaced apart from each other along a first direction D1, each of the plurality of through vias 400 may be disposed spaced apart from each other along the first direction D1, and each of the plurality of lower electrodes 200 may be disposed spaced apart from each other along the first direction D1.

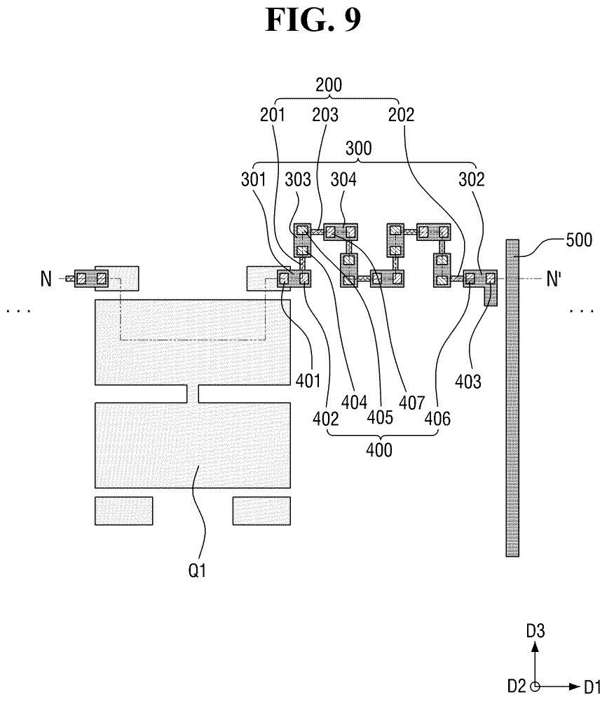

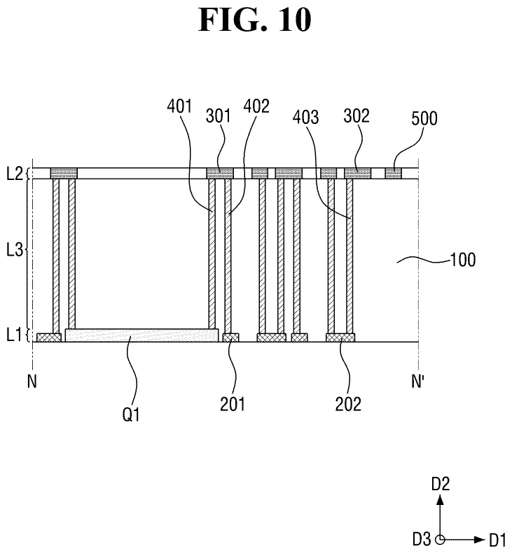

In the following, a resonant circuit device comprising a qubit according to some embodiments of the present disclosure will be described with reference to FIGS. 9 and 10. For clarity of description, any part that overlaps with what has already been described will be either simplified or omitted.

FIG. 9 is a plan view of a resonant circuit device comprising a qubit according to some embodiments of the present disclosure. FIG. 10 is a cross-sectional view taken along the line N-N′ in FIG. 9.

The illustration of an insulating layer L3 and an insulating material 100 is omitted in FIG. 9 for clarity.

Referring to FIGS. 9 and 10, a plurality of upper electrodes 300 of the resonant circuit device comprising a qubit according to some embodiments of the present disclosure may not be arranged in a line between a first qubit Q1 and a transmission line 500.

The resonant circuit device comprising a qubit according to some embodiment of the present disclosure may be included in a qubit chip. In addition, the resonant circuit device comprising a qubit according to some embodiment of the present disclosure may be included in a quantum computer QPU circuit.

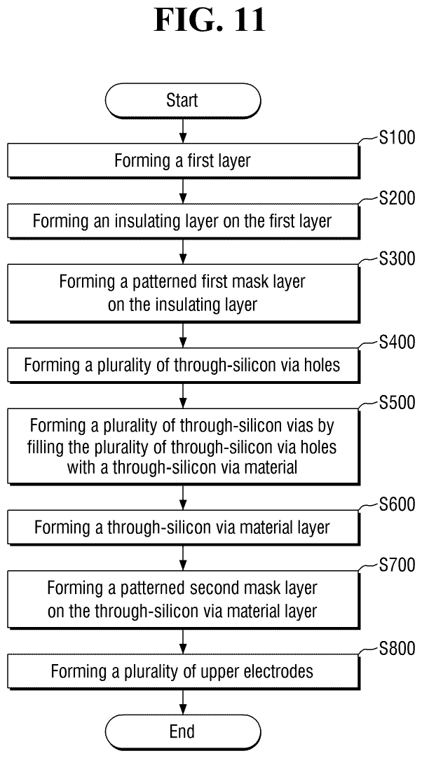

In the following, a method of manufacturing a resonant circuit device comprising a qubit according to some embodiments of the present disclosure will be described with reference to FIGS. 11 to 17. For clarity of description, any part that overlaps with what has already been described will be either simplified or omitted.

FIG. 11 is a flowchart for describing a method of manufacturing a resonant circuit device comprising a qubit according to some embodiments of the present disclosure. The drawings below show that a first qubit and lower electrodes are spaced apart in a certain direction and the lower electrodes extend along a certain direction, but they are not limited thereto. Even in embodiments where the first qubit and the lower electrodes are spaced apart in different directions or where the lower electrodes extend along a direction different from the certain direction (e.g., FIGS. 5, 6, 9, and 10), forming steps may be the same, except that the disposition of the lower electrodes and the disposition locations of a plurality of through via holes 400h using mask patterns are different.

Referring to FIG. 11, the method of manufacturing a resonant circuit device comprising a qubit according to some embodiments of the present disclosure may comprise forming a first layer (S100).

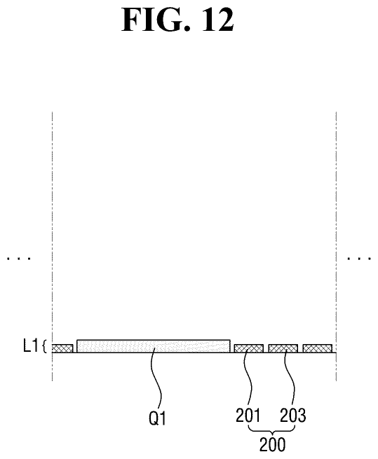

FIG. 12 is part of a cross-sectional view for describing step S100 of FIG. 11.

Referring to FIGS. 11 and 12, a first layer L1 comprising a first qubit Q1 and a plurality of lower electrodes 200 may be formed. The plurality of lower electrodes 200 may be spaced apart from the first qubit Q1.

In some embodiments, the plurality of lower electrodes 200 may be connected to one of a second qubit Q2 and a transmission line 500. The plurality of lower electrodes 200 may be arranged in a line between the first qubit Q1 and one of the second qubit Q2 and the transmission line 500.

In some embodiments, the plurality of lower electrodes 200 may be connected to one of the second qubit Q2 and the transmission line 500. The plurality of lower electrodes 200 may not be arranged in a line between the first qubit Q1 and one of the second qubit Q2 and the transmission line 500.

Referring again to FIG. 11, the method of manufacturing a resonant circuit device comprising a qubit according to some embodiments of the present disclosure may comprise forming an insulating layer on the first layer (S200). The method of manufacturing a resonant circuit device comprising a qubit according to some embodiments of the present disclosure may comprise forming a patterned first mask layer on the insulating layer (S300).

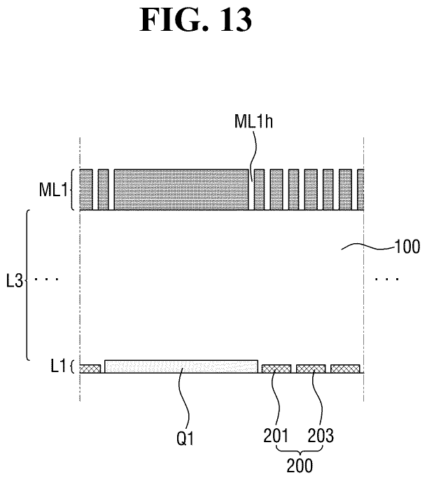

FIG. 13 is part of a cross-sectional view for describing steps S200 and S300 of FIG. 11.

Referring to FIGS. 11 and 13, an insulating layer L3 may be formed on the first layer L1. An insulating material 100 may be deposited to fill the gaps formed in the first layer L1 (e.g., between the first qubit Q1 and a first lower electrode 201, and between the first lower electrode 201 and a second lower electrode 202) and to have a certain height, thereby forming the insulating layer L3.

A patterned first mask layer ML1 may be formed on the insulating layer L3. The first mask layer ML1 may comprise a plurality of first mask holes ML1h, and the plurality of first mask holes ML1h may expose part of the insulating layer L3.

Referring again to FIG. 11, the method of manufacturing a resonant circuit device comprising a qubit according to some embodiments of the present disclosure may comprise forming a plurality of through via holes (S400).

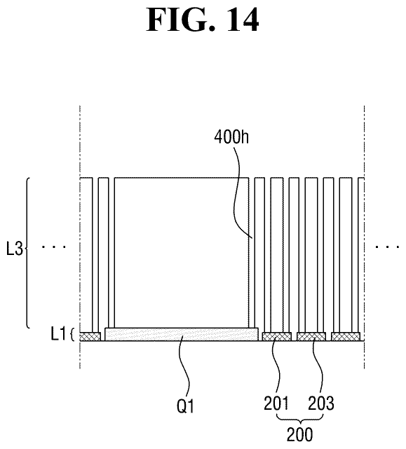

FIG. 14 is part of a cross-sectional view for describing step S400 of FIG. 11.

Referring to FIGS. 11 and 14, a plurality of through via holes 400h may be formed in the insulating layer L3 based on the patterned first mask layer ML1. The plurality of through via holes 400h may expose part of the first qubit Q1 through the insulating layer L3. The plurality of through via holes 400h may expose part of each of the plurality of lower electrodes 200 through the insulating layer L3. After the plurality of through via holes 400h is formed, the first mask layer ML1 in FIG. 13 may be removed.

Referring again to FIG. 11, the method of manufacturing a resonant circuit device comprising a qubit according to some embodiments of the present disclosure may comprise forming a plurality of through vias by filling the plurality of through via holes with a through via material (S500).

The method of manufacturing a resonant circuit device comprising a qubit according to some embodiments of the present disclosure may comprise forming a through via material layer (S600).

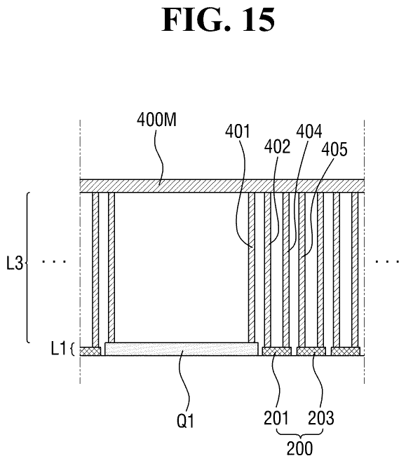

FIG. 15 is part of a cross-sectional view for describing steps S500 and S600 of FIG. 11.

Referring to FIGS. 11 and 15, a plurality of through vias 400 may be formed in the insulating layer L3 by filling the plurality of through via holes 400h with the through via material. The through via material may be formed, on the plurality of through vias 400, to cover the upper surface of the insulating layer L3. A through via material layer 400M may be formed on the upper surface of the insulating layer L3.

Referring again to FIG. 11, the method of manufacturing a resonant circuit device comprising a qubit according to some embodiments of the present disclosure may comprise forming a patterned second mask layer on the through via material layer (S700).

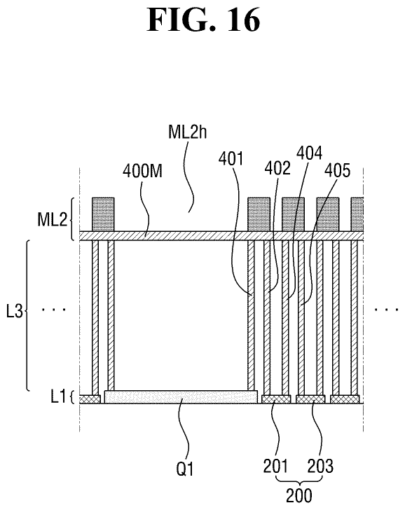

FIG. 16 is part of a cross-sectional view for describing step S700 of FIG. 11.

Referring to FIGS. 11 and 16, a patterned second mask layer ML2 may be formed on the through via material layer 400M. The patterned second mask layer ML2 may comprise a plurality of second mask holes ML2h. The plurality of second mask holes ML2h may expose part of the through via material layer 400M.

Referring again to FIG. 11, the method of manufacturing a resonant circuit device comprising a qubit according to some embodiments of the present disclosure may comprise forming a plurality of upper electrodes (S800).

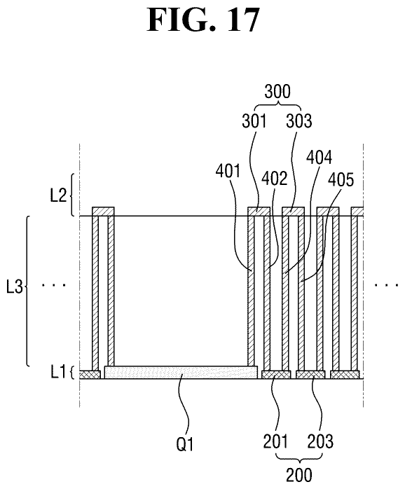

FIG. 17 is part of a cross-sectional view for describing step S800 of FIG. 11.

Referring to FIGS. 11 and 17, a plurality of upper electrodes 300 may be formed based on the patterned second mask layer ML2. The part of the through via material layer 400M exposed by the plurality of second mask holes ML2h may be removed. As a result, the upper surface of the insulating layer L3 may be exposed again. Each of the plurality of upper electrodes 300 may be connected to each of the plurality of through vias 400.

While the inventive concept has been particularly shown and described with reference to exemplary embodiments thereof, it will be understood by those of ordinary skill in the art that various changes in form and details may be made therein without departing from the spirit and scope of the inventive concept as defined by the following claims. It is therefore desired that the embodiments be considered in all respects as illustrative and not restrictive, reference being made to the appended claims rather than the foregoing description to indicate the scope of the disclosure.

What is claimed is:

1. A resonant circuit device comprising a qubit, comprising:
a first qubit;
a first lower electrode disposed spaced apart from the first qubit in a first direction;
an insulating layer disposed on the first qubit and the first lower electrode;
a first upper electrode disposed on the insulating layer;
a first through via connecting the first qubit and the first upper electrode and disposed through the insulating layer; and
a second through via connecting the first upper electrode and the first lower electrode and disposed through the insulating layer.

2. The resonant circuit device comprising a qubit of claim 1, further comprising:
a plurality of upper electrodes disposed on the insulating layer and spaced apart from each other;
a plurality of lower electrodes disposed under the insulating layer and spaced apart from each other; and
a plurality of through vias connecting each of the plurality of upper electrodes and each of the plurality of lower electrodes and passing through the insulating layer,
wherein the plurality of upper electrodes comprises the first upper electrode,
the plurality of lower electrodes comprises the first lower electrode,
the plurality of through vias comprises the second through via, and
the plurality of through vias is spaced apart from the first through via, and
wherein a resonant frequency of the resonant circuit device is determined based on a combined number of the first through via and the plurality of through vias.

3. The resonant circuit device comprising a qubit of claim 1, wherein the first through via and the second through via extend along a second direction intersecting the first direction.

4. The resonant circuit device comprising a qubit of claim 1, wherein a lower part of the first through via is in direct contact with the first qubit,
an upper part of the first through via is in direct contact with a first portion of the first upper electrode,
an upper part of the second through via is in direct contact with a second portion of the first upper electrode, and
a lower part of the second through via is in direct contact with a first portion of the first lower electrode.

5. The resonant circuit device comprising a qubit of claim 1, further comprising:
a second qubit disposed spaced apart from the first qubit;
a second upper electrode spaced apart from the first upper electrode and disposed on the insulating layer;
a second lower electrode spaced apart from the first lower electrode and disposed under the insulating layer; and
a third through via connecting the second upper electrode and the second qubit and disposed through the insulating layer,
wherein the first lower electrode and the second lower electrode are disposed between the first qubit and the second qubit.

6. The resonant circuit device comprising a qubit of claim 5, further comprising:
a plurality of upper electrodes disposed on the insulating layer and spaced apart from each other;
a plurality of lower electrodes disposed under the insulating layer and spaced apart from each other; and
a plurality of through vias connecting each of the plurality of upper electrodes and each of the plurality of lower electrodes and passing through the insulating layer,
wherein the plurality of upper electrodes comprises the first upper electrode and the second upper electrode,
the plurality of lower electrodes comprises the first lower electrode and the second lower electrode,
the plurality of through vias comprises the second through via, and
the plurality of through vias is spaced apart from each of the first through via and the third through via.

7. The resonant circuit device comprising a qubit of claim 6, wherein each of the plurality of upper electrodes is disposed spaced apart from each other along the first direction, and
each of the plurality of through vias is disposed spaced apart from each other along the first direction.

8. The resonant circuit device comprising a qubit of claim 6, wherein each of the plurality of upper electrodes comprises:
a first upper electrode group extending in the first direction; and
a second upper electrode group extending along a third direction intersecting the first direction,
wherein the plurality of through vias further comprises a fourth through via spaced apart from the second through via in the third direction.

9. The resonant circuit device comprising a qubit of claim 1, further comprising:
a transmission line spaced apart from the first upper electrode and disposed on the insulating layer;
a second upper electrode spaced apart from the first upper electrode and disposed on the insulating layer;
a second lower electrode spaced apart from the first lower electrode and disposed under the insulating layer; and
a third through via connecting the second upper electrode and the second lower electrode and disposed through the insulating layer,
wherein the second upper electrode is disposed between the first upper electrode and the transmission line, and
the second upper electrode and the transmission line are connected to each other.

10. The resonant circuit device comprising a qubit of claim 9, further comprising:
a plurality of upper electrodes disposed on the insulating layer and spaced apart from each other;
a plurality of lower electrodes disposed under the insulating layer and spaced apart from each other; and
a plurality of through vias connecting each of the plurality of upper electrodes and each of the plurality of lower electrodes and passing through the insulating layer,
wherein the plurality of upper electrodes comprises the first upper electrode and the second upper electrode,
the plurality of lower electrodes comprises the first lower electrode and the second lower electrode,
the plurality of through vias comprises the second through via, and
the plurality of through vias is spaced apart from each of the first through via and the third through via.

11. The resonant circuit device comprising a qubit of claim 1, wherein the first upper electrode and the first through via include the same material, and the first lower electrode includes a material different from that included in each of the first upper electrode and the first through via.

12. The resonant circuit device comprising a qubit of claim 10, wherein each of the plurality of upper electrodes comprises:
a first upper electrode group extending in the first direction; and
a second upper electrode group extending along a third direction intersecting the first direction,
wherein the plurality of through vias further comprises a fourth through via spaced apart from the second through via in the third direction.

13. A resonant circuit device comprising a qubit, comprising:
a first layer comprising a first qubit and a plurality of lower electrodes disposed spaced apart from the first qubit in a first direction;
an insulating layer on the first layer; and
a second layer disposed on the insulating layer and comprising a plurality of upper electrodes,
wherein the insulating layer comprises:
a plurality of through vias connecting each of the plurality of lower electrodes and each of the plurality of upper electrodes and passing through the insulating layer; and
a first through via connecting a first portion of a first upper electrode of the plurality of upper electrodes and the first qubit and passing through the insulating layer, and
wherein a resonant frequency is determined based on a combined number of the plurality of through vias and the first through via.

14. The resonant circuit device comprising a qubit of claim 13, wherein a lower part of the first through via is in direct contact with the first qubit,
an upper part of the first through via is in direct contact with a first portion of the first upper electrode,
the plurality of through vias comprises a second through via, and the plurality of lower electrodes comprises a first lower electrode,
an upper part of the second through via is in direct contact with a second portion of the first upper electrode, and
a lower part of the second through via is in direct contact with a first portion of the first lower electrode.

15. The resonant circuit device comprising a qubit of claim 13, further comprising:
a second qubit spaced apart from the first qubit and disposed in the first layer,
wherein the plurality of upper electrodes comprises a second upper electrode spaced apart from the first upper electrode,
the plurality of lower electrodes comprises a first lower electrode disposed between the first qubit and the second qubit, and
the plurality of through vias comprises a second through via connecting a second portion of the first upper electrode and a first portion of the first lower electrode and passing through the insulating layer.

16. The resonant circuit device comprising a qubit of claim 15, wherein each of the plurality of upper electrodes is disposed spaced apart from each other along the first direction, and
each of the plurality of through vias is disposed spaced apart from each other along the first direction.

17. The resonant circuit device comprising a qubit of claim 15, wherein each of the plurality of upper electrodes comprises:
a first upper electrode group extending in the first direction; and
a second upper electrode group extending along a third direction intersecting the first direction,
wherein the plurality of through vias further comprises a fourth through via spaced apart from the second through via in the third direction.

18. The resonant circuit device comprising a qubit of claim 13, further comprising:
a transmission line spaced apart from the first upper electrode and disposed on the insulating layer,
wherein the plurality of upper electrodes comprises a second upper electrode spaced apart from the first upper electrode,
the plurality of lower electrodes comprises a first lower electrode and a second lower electrode disposed between the first qubit and the transmission line and spaced apart from each other,
the plurality of through vias comprises a second through via connecting the second upper electrode and the second lower electrode and disposed through the insulating layer,
the second upper electrode is disposed between the first upper electrode and the transmission line, and
the second upper electrode and the transmission line are connected to each other.

19. The resonant circuit device comprising a qubit of claim 18, wherein each of the plurality of upper electrodes is disposed spaced apart from each other along the first direction, and
each of the plurality of through vias is disposed spaced apart from each other along the first direction.

20. A method of manufacturing a resonant circuit device comprising a qubit, comprising:
forming a first layer comprising a first qubit and a plurality of lower electrodes disposed spaced apart from the first qubit;
forming an insulating layer on the first layer;
forming a patterned first mask layer on the insulating layer;
forming a plurality of through via holes, which passes through the insulating layer, exposes part of the first qubit, and exposes part of each of the plurality of lower electrodes, based on the patterned first mask layer;
forming a plurality of through vias by filling the plurality of through via holes with a through via material;
forming a through via material layer by covering an upper surface of the insulating layer and the plurality of through vias with the through via material;
forming a patterned second mask layer on the through via material layer; and
forming a plurality of upper electrodes, which exposes part of the upper surface of the insulating layer and is connected to each of the plurality of through vias, based on the patterned second mask layer.
